(19) United States
(12) Patent Application Publication
(10) Pub. No.: US 2024/0201241 A1
(43) Pub. Date: Jun. 20, 2024

(54) MEASUREMENT ARRANGEMENT, MEASUREMENT SETUP, MEASUREMENT SYSTEM AND METHOD FOR DETERMINING A BEAMFORMING CHARACTERISTIC OF A DEVICE UNDER TEST

(71) Applicant: Advantest Corporation, Tokyo (JP)

(72) Inventors: José MOREIRA, Stuttgart (DE); Max NEUWEILER, Böblingen (DE); Jochen ZAISER, Böblingen (DE); Arimoto KIKUCHI, Tokyo (JP)

(21) Appl. No.: 18/589,333

(22) Filed: Feb. 27, 2024

Related U.S. Application Data
(63) Continuation of application No. PCT/EP2021/073817, filed on Aug. 27, 2021.

(51) Int. Cl. G01R 29/08; G01R 29/10

(52) U.S. Cl. CPC G01R 29/0871; G01R 29/10

(57) ABSTRACT

Embodiments according to the disclosure have a measurement arrangement for an automated test equipment (ATE), for determining a beamforming characteristic of a device under test (DUT), wherein the measurement arrangement is adapted to carry an antenna and wherein the measurement arrangement is configured to manipulate position of the antenna relative to the DUT, to allow for a determination of the beamforming characteristic of the DUT when the DUT is coupled to a load board, and when the load board is electrically coupled to a test head of the ATE. Furthermore, the measurement arrangement is configured to be attached to the test head of the ATE or to a load board frame attached to the test head of the ATE.

### CROSS-REFERENCE TO RELATED APPLICATION

This application is a continuation of copending International Application No. PCT/EP2021/073817, filed Aug. 27, 2021, which is incorporated herein by reference in its entirety.

### TECHNICAL FIELD

Embodiments according to the disclosure are related to a measurement arrangement, a measurement setup, a measurement system, and a method for determining a beamforming characteristic of a device under test. Embodiments are related to a beamforming measurement on ATE (automated test equipment).

### BACKGROUND OF THE DISCLOSURE

Antennas are important components of many modern-day electronic devices. Consequently, these antennas may be tested in order to verify their performance. For modern communication, especially 5G, compliant antenna measurement approaches are of special interest. The third-generation partnership project (3GPP) (5G) standard defines, for example, inter alia, the following over the air (OTA) test methods for 5G-NR: Direct far field (DFF), indirect far field (IFF), e.g., compact antenna test range (CATR) and near field to far field (NFTF) transformation. FIGS. 1 to 3 show examples for such an antenna measurement approaches.

FIG. 1 shows a DFF measurement setup of user equipment (UE) radio frequency (RF) characteristics. A beam 110 of a link antenna 120 for beam steering is measured in the direct far field by a measurement antenna 130 for center and off-center of beam measurements.

FIG. 2 shows an IFF method (CATR) measurement setup of UE RF characteristics. A PC 210 controls a signal generator 220 in order to provide a signal to a feed antenna 230. A beam generated by antenna 230 is reflected by a reflector 240 and measured by a movable measurement device 250. Therefore, the measurement device 250 may measure the indirect far field of the beam of the feed antenna 230. The measurement device 250 is controlled by the PC 210 via a positioner controller 260.

FIG. 3 shows, for example, a typical NFTF measurement setup of EIRP (effective isotropic radiated power)/TRP (total radiated power) measurements. FIG. 3 shows, as an example, a Link Antenna 310 that may provide a stimulus for a device 320. Device 320 may emit a signal in response to the stimulus from the Link Antenna 310. A reference signal provider 330 may provide a reference signal for the evaluation of the NFTF measurements. In addition, FIG. 3 shows Measurement/Link Antennas 340, that may be used to measure signals provided by the device 320 and/or the reference signal provider 330. Reference signal provider 330 and/or Measurement/Link Antennas 340 may be configured to provide for a calibration of the measurement setup.

FIGS. 1 to 3 may show FIGS. 5.2.1.1-1, 5.2.3.1-1, and 5.2.4.1-1 from the 3GPP TR 38.810 V16 1.0 (2018-02) documents, as examples for DFF, IFF and NFTF measurements.

There are commercial solutions one can buy for each of these approaches, for example the approaches shown in FIGS. 1 to 3, but they are all very large in size and also cannot be integrated with a commercial semiconductor automated test equipment (ATE) system. Usually, they are used together with bench instrumentation. FIG. 4 shows an example of an indirect far field 5G compliant reference measurement setup.

Consequently, it is desired to get a concept for determining antenna characteristics, such as a beamforming characteristic, which provides a better compromise between integrability, measurement accuracy and costs.

### SUMMARY

An embodiment may have a measurement arrangement for an automated test equipment (ATE), for determining a beamforming characteristic of a device under test (DUT), wherein the measurement arrangement is adapted to carry an antenna, and wherein the measurement arrangement is configured to manipulate a position of the antenna, relative to the DUT, to allow for a determination of the beamforming characteristic of the DUT when the DUT is coupled to a load board, and when the load board is electrically coupled to a test head of the ATE; and wherein the measurement arrangement is configured to be attached to the test head of the ATE or to a load board frame attached to the test head of the ATE.

According to another embodiment, a measurement setup may have: a measurement arrangement according to the disclosure as mentioned above; and the load board frame, wherein the load board frame is configured to be coupled with the load board; and wherein the load board frame is configured to be attached to the test head; and wherein the measurement arrangement is configured to be attached to the load board frame.

According to another embodiment, a measurement system may have: a test head; a load board; and a measurement setup according to the disclosure as mentioned above; wherein the load board frame is attached to the test head; and wherein the load board is mechanically coupled to the load board frame.

According to still another embodiment, a method for determining a beamforming characteristic of a device under test (DUT), using an automated test equipment (ATE) and a measurement arrangement, may have the steps of: manipulating a position of an antenna, carried by the measurement arrangement, relative to the DUT, while the DUT is coupled to a load board, and while the load board is electrically coupled to a test head of the ATE, and wherein the measurement arrangement is attached to the test head of the ATE or to a load board frame attached to the test head of the ATE; and determining the beamforming characteristic of the device under test (DUT).

Embodiments according to the disclosure comprise a measurement arrangement for an automated test equipment (ATE), for determining a beamforming characteristic of a device under test (DUT), wherein the measurement arrangement is adapted to carry an antenna and wherein the measurement arrangement is configured to manipulate position of the antenna relative to the DUT, to allow for a determination of the beamforming characteristic of the DUT when the DUT is coupled to a load board, and when the load board is electrically coupled to a test head of the ATE or in other words coupled to an ATE system test head. Furthermore, the measurement arrangement is configured to be attached to the test head of the ATE or to a load board frame attached to the test head of the ATE.

Further embodiments according to the disclosure comprise a measurement setup comprising a measurement arrangement according to embodiments of the disclosure and the load board frame, wherein the load board frame is configured to be coupled, e.g. mechanically, with the load board. In addition, the load board frame is configured to be attached to the test head and the measurement arrangement is configured to be attached to the load board frame.

Further embodiments according to the disclosure comprise a measurement system comprising a test head, a load board, and a measurement setup according to embodiments of the disclosure. In addition, the load board frame is attached to the test head and the load board is mechanically coupled to the load board frame.

Further embodiments according to the disclosure comprise a method for determining a beamforming characteristic of a device under test (DUT), using an automated test equipment (ATE) and a measurement arrangement. The method comprises manipulating a position, e.g. an elevation and/or an azimuth, of an antenna, carried by the measurement arrangement, relative to the DUT, while the DUT is coupled to a load board, and while the load board is electrically coupled to a test head of the ATE, and wherein the measurement arrangement is attached to the test head of the ATE or to a load board frame attached to the test head of the ATE. Furthermore, the method comprises determining the beamforming characteristic of the device under test, e.g. based on signals from the antenna.

Embodiments according to the disclosure are based on the idea to determine a beamforming characteristic of a device under test with a measurement arrangement for an automated test equipment. The measurement arrangement may, for example, be a module or an add-on module for the automated test equipment. Therefore, the measurement arrangement may be easily attached and/or removed from the ATE. As a result, testing of a device under test may be performed with increased flexibility. In addition, costs and testing time may be reduced because of the modular characteristics of such a measurement arrangement. The measurement arrangement may, for example, comprise a circular carrier member, having a circular circumference and a ring structure on which a movable antenna carrier structure is arranged. In order to determine the beamforming characteristics of the device under test the measurement arrangement is adapted to carry an antenna, however, the antenna may optionally be part of the measurement arrangement. Furthermore, manipulation of the position of the antenna may comprise manipulation of an elevation and/or an azimuth of the antenna, for example, when the antenna is attached. Moreover, the DUT may, for example, be a radiating DUT, a transmitting DUT and/or a DUT comprising one or more antennas. The DUT may, for example, be an antenna in package (AIP) module.

Consequently, such a measurement arrangement or measurement module may be used in order to measure a, for example complete, beam shape of the device under test using the automated test equipment and therefore being able to perform a plurality of other, for example, additional tests on the device under test. Hence, determination of a beamforming characteristic may, for example, be integrated in a test routine with reduced costs and time effort.

In addition, the measurement arrangement may, for example, be configured to be removably, for example, directly or indirectly, for example, with a load board frame in between a test head of the automated test equipment and the measurement arrangement, attached to the test head of the automated test equipment or to a load board frame attached to the test head of the automated test equipment. As an example, the measurement arrangement may, for example, be flexible, and/or for example be flexibly attached to the test head of the automated test equipment or to a load board frame attached to the test head of the automated test equipment. The measurement arrangement may be configured to be, for example easily and/or quickly, attached to and/or disengaged from the test head or load board frame. The test head may, for example, have electrical connections, for example pogo pins, for connecting to the load board, for establishing an electrical connection between the test head and the DUT via the load board, for example, when the load board of the ATE is already attached to the test head of the ATE.

Consequently, a mechanical and electrical connection from the automated test equipment, for example via a load board frame, may be established easily and with low time effort.

According to further embodiments of the disclosure, the measurement arrangement is configured to be attached to the test head or the load board frame attached to the test head, for example directly or indirectly, with a load board frame in between, when the load board is already electrically coupled, or for example attached, to the test head, e.g., without removing the load board, and/or when the load board is already attached to the load board frame.

This may allow integrating the determination of a beamforming characteristic of a device under test in a test routine without a significant increase in time, effort, and costs. Electrical tests on the device under test may be performed and, without removing the load board or the load board together with its load board frame, the measurement arrangement may be attached. Consequently, efficiency and flexibility of the automated test equipment may be increased.

According to further embodiments of the disclosure, the measurement arrangement is configured to be supported mechanically by a test head or by the load board frame attached to the test head. Mechanical support by the test head or by the load board frame enables quick attaching and removing of the measurement arrangement without time consuming disassembly, for example of housing parts of the automated test equipment, in order to mechanically connect the measurement arrangement.

According to further embodiments of the disclosure, the measurement arrangement is configured to manipulate an elevation and/or an azimuth of the antenna, relative to a DUT position, for example a DUT socket, for example relative to the DUT when the DUT is coupled to the load board, in order to manipulate the position of the antenna. This allows a two- and/or three-dimensional determination of the beamforming characteristic of the device under test.

According to further embodiments of the disclosure, the measurement arrangement comprises an actuator, for example a motor. Furthermore, the actuator is configured to manipulate the position, for example an elevation and/or an azimuth, of the antenna relative to a device under test position, for example a DUT socket, for example relative to the DUT when the DUT is coupled to the load board. In addition or alternatively, the measurement arrangement comprises means to manipulate the position, for example an elevation and/or an azimuth, of the antenna manually, relative to a DUT position, for example a DUT socket, for example relative to the DUT, when the DUT is coupled to the load board. The actuator may be used for a fully automated manipulation of the position of the antenna, for example for performing an automated test routine on the device under test, reducing testing costs and testing times. For lower cost testing applications, means to manipulate the position of the antenna manually may be provided.

According to further embodiments of the disclosure, the measurement arrangement is configured to provide a measurement information for determining the beamforming characteristic of the device under test. The measurement information may, for example, be processed by the automated test equipment enabling a fully automated test routine. This may reduce costs and testing times.

According to further embodiments of the disclosure, the measurement arrangement comprises a central part and in the central part an opening for the load board frame, for example, such that the load board can contact the load board interface, for example, such that measurement arrangement can be put on the load board frame. The central part may be configured to be attached or pushed or pinned upon an edge, for example an outer edge of the load board frame. The contact or supporting area in between central part and load board frame may be adjacent or neighboring or surrounding the area of the load board frame on which the load board is attached or mounted. Consequently, the measurement arrangement may be attached or removed without removing the load board from the load board frame or the load board frame from the test head. Such a modular measurement arrangement may allow a reduction in testing time and therefore testing costs. On the other hand, the load board may, for example, be removed from the load board frame without removing the measurement arrangement. This may further increase the flexibility of the automated test equipment.

According to further embodiments of the disclosure, the central part is configured to be attached to the load board frame. The central part may, for example, be attached mechanically on an edge of the load board frame. The central part or the load board frame may comprise a grove in order to attach the respective other part. The load board frame may comprise a locking mechanism in order to keep the central part in place.

According to further embodiments of the disclosure, the measurement arrangement comprises a ring structure around the central part, wherein the ring structure is configured to be rotatable around the central part. Furthermore, the measurement arrangement comprises a first rotary joint and a carrier structure, wherein the carrier structure is attached to the first rotary joint and wherein the carrier structure is adapted to carry the antenna. In addition, the first rotary joint is configured to allow for a manipulation of an elevation of the carrier structure relative to the central part via a rotation of the carrier structure. The carrier structure and the first rotary joint may, for example, be attached to the ring structure. Therefore, by rotating the ring structure around the central part, an azimuth of the antenna carried by the carrier structure may be adapted. The central part may comprise the before mentioned opening for the load board frame and therefore, for example, the load board with a device under test. By rotating the central part and the first rotary joint an elevation and/or an azimuth of an antenna of the carrier structure may be manipulated relative to the device under test in order to measure its beamforming characteristics. This may allow for an easy to attach and easy to remove measurement arrangement for the automated test equipment.

According to further embodiments of the disclosure, the opening, for example a rectangular opening, for the load board frame is formed, such that the measurement arrangement can be attached to and/or removed from the test head, while the load board is attached to the load board frame which is attached to the test head. Optionally, the central part comprises a circular outer boundary or a circular circumference. By attaching and/or removing the measurement arrangement while the load board is attached to the load board frame a test routine may be extended by a determination of a beamforming characteristic of a device under test attached to the load board without time consuming conversion of the automated test equipment. Therefore, the edge of the opening of the measurement arrangement may be attached or fixed upon an outer edge of the load board frame, such that the opening itself provides space for the load board. The measurement arrangement may be produced as an add-on module for the automated test equipment, optionally together with a corresponding load board frame, and may therefore provide a flexible and inexpensive test equipment extension for a plurality of automated test equipment.

According to further embodiments of the disclosure, the ring structure and the central part are arranged in the same plane or in two planes that are parallel to each other. There may be an offset in between the planes of the central part and the ring structure, for example, in order to provide low cost and/or easy to fabricate and/or easy to maintain bearing elements in between the ring structure and the central part. In addition, the central part may be offset to the ring structure in order to extend the movement range of the carrier structure extending the range of elevation angles.

According to further embodiments of the disclosure, the measurement arrangement comprises the first rotary joint and a second rotary joint, wherein the rotary joints are attached to opposite sides of the ring structure. In addition, the first and second rotary joints are arranged, such that they comprise a common rotation axis, wherein the rotation axis and a normal vector of the plane of the central part and/or of the plane of the ring structure are orthogonal with a tolerance of less than 0.01 degree, less than 0.1 degree or less than 1 degree or less than 5 degrees. Furthermore, the carrier structure is attached to the first and the second rotary joint and the first and second rotary joints are configured to allow for a manipulation of an elevation of the carrier structure, relative to the central part, via a rotation of the carrier structure around the common rotation axis of the first and second rotary joint. With a second rotary joint opposite to the first rotary joint a stiffness of the bearing of the carrier structure may be increased, in order to manipulate the position of the antenna more accurately. In addition, such a setup may be more robust, such that removing an attaching the measurement arrangement frequently to or from the test equipment may not result in warping of the measurement arrangement.

According to further embodiments of the disclosure, the measurement arrangement is configured to center the antenna, when attached to the carrier structure, over the device under test, or for example over a DUT position or DUT socket, when the DUT is coupled to the load board and when the measurement arrangement and the load board are attached to the load board frame, the load board frame being attached to the test head and when the carrier structure is rotated to a position wherein an elevation between the carrier structure and the load board is 90 degrees. With the antenna centered over the device under test a beamforming characteristic of the device under test may be determined without any offset.

According to further embodiments of the disclosure, the ring structure comprises a plurality of bearing elements and the ring structure is supported by the central part via the bearing elements, such that the ring structure can rotate around the central part.

The central part may be, for example, mechanically supported by the load board frame and the ring structure may be supported by the central part via the bearing elements, such that the mechanical contact to the automated test equipment is in between central part and load board frame, which may enable easily attaching and removing the measurement arrangement and, in addition, may enable free movement of the ring structure, for example, in order to manipulate the azimuth.

According to further embodiments of the disclosure, the measurement arrangement comprises an absorptive structure and the absorptive structure is configured to absorb electromagnetic waves. The absorptive structure may mitigate or may prevent undesirable reflections of antenna signals from surfaces of the measurement arrangement. For some applications, a measurement may be desired that may allow to extract an information about a real-world situation, for example with antenna signals propagating through open space. A measurement antenna configured to measure signals of such a setup may have to be mounted, fastened and/or connected to a supporting structure, e.g. a carrier structure, of a testing arrangement, e.g. measurement arrangement. Hence, metal surfaces and connecting elements, e.g. the carrier structure, may be present that may distort or alternate the propagating signals by introducing reflections, e.g. causing interference. Therefore, a reduction of reflections via the absorptive structure may improve measurements.

According to further embodiments of the disclosure, the measurement arrangement comprises the absorptive structure, e.g. as explained before, and the absorptive structure is configured to absorb electromagnetic waves and the absorptive structure is arranged on the carrier structure. In addition, the absorptive structure is configured to reduce an influence of reflections of electromagnetic waves from the carrier structure on a measurement of the measurement antenna. The carrier structure may comprise a metal material in order to provide stability for the measurement antenna being attached to the carrier structure. Hence, the carrier structure may cause a large amount of reflections, that may influence the measurement of the measurement antenna. Therefore, arranging or attaching of the absorptive structure on or to the carrier structures may improve measurement accuracy, e.g. significantly.

According to further embodiments of the disclosure, the measurement arrangement comprises a calibration reference antenna, wherein the calibration reference antenna is configured to provide a reference signal for a calibration of the measurement antenna. The calibration reference antenna may be configured to calibrate the measurement arrangement, for example, by providing a predetermined signal to the measurement antenna. Hence, the measurement antenna may be calibrated according to the predetermined signal.

According to further embodiments of the disclosure, the calibration reference antenna is configured to be, for example, removably, arranged in the center of the central part of the measurement setup, e.g., instead of the load board and DUT. This placement of the calibration reference antenna may allow for a three-dimensional calibration of the measurement antenna. The reference antenna may, for example be configured to be attached to the load board frame and/or to the central part itself. The reference antenna may optionally comprise a mount for attachment to the load board frame and/or the central part. The reference antenna may, for example, be configured to be attached to and/or removed from the load board frame and/or the central part without removing the measurement arrangement from the load board frame and without removing measurement arrangement and load board frame, e.g. a measurement setup according to embodiments, from a test head. As an example, the load board may be removed, then the reference antenna may be attached to the measurement setup in order to calibrate the measurement antenna. Thereafter, the reference antenna may be removed and the load board may be reattached in order to start testing a device under test, that may be attached to the load board. With the calibration reference antenna in the middle, the measurement antenna may be moved around the calibration reference antenna, e.g. via manipulating an azimuth and/or elevation of the measurement antenna. Therefore, the measurement antenna may be calibrated using a plurality of measurements points, and, may, for example, be calibrated, depending on a specific elevation and/or azimuth, for example, further taking into account reflections from structural elements, e.g. the carrier structure, of the measurement arrangement. Influences of such reflections may, for example, be mitigated by an azimuth and/or elevation dependent calibration. Therefore, measurements with high accuracy may be provided.

According to embodiments of the disclosure, the measurement arrangement comprises a second actuator and the second actuator is configured to rotate the ring structure around the central part. Optionally the second actuator may be configured to move the ring structure automatically, in order to change an azimuth and/or may, for example be configured to move the ring structure, in order to change an azimuth of the antenna automatically. In other words, the second actuator that moves or may be configured to move the ring structure may, for example in fact, be configured to change or may be changing the antenna azimuth automatically. Hence embodiments comprising the first and second actuator may provide fully automated manipulation of elevation and azimuth of the antenna relative to a device under test. Actuation of the rotation may enable a fully automated test routine. Therefore, testing costs and testing time may be reduced.

According to further embodiments of the disclosure, the load board frame is configured to provide for a spacing, for example a garage space, e.g., an additional space, between a test head and a load board. In addition, the load board frame may be configured to allow for a routing of one or more cables for feeding signals from the test head to the load board and/or to allow for a routing of one or more cables for guiding signals from the load board to the test head and/or to allow for routing of one or more cables from the test head to the measurement arrangement. In addition or alternatively the load board frame may be configured to allow for a storing of additional components in the spacing. The spacing may allow easy access, for example, for maintenance and for simplified cable organization. It may, for example, allow that additional large custom components can be added by the user. The load board may allow the user to add small size components but the garage space below the load board may allow for very large components or, for example, even a full compact measurement instrument. Optionally, the spacing may, for example, be covered by a casing or cover structure.

According to further embodiments of the disclosure, the test head is configured to perform one or more electrical tests on the DUT, for example, under the control of a test program. The one or more electrical tests may, for example, be executed in the absence of the antenna or may not use the antenna. The measurement arrangement according to embodiments may be utilized in a plurality of measurement systems, for example, comprising arbitrary automated test equipment, for example, a standard range of possible tests to be performed by the automated test equipment.

According to further embodiments of the disclosure, the measurement arrangement is configured to be controlled by the test head. This may allow for a fully automated test routine. Signal simulation and signal evaluation may be performed via the test head in order to determine the beamforming characteristics of a device under test.

According to further embodiments of the disclosure, the measurement arrangement is configured to manipulate the position of the antenna and/or to provide the measurement information for determining the beamforming characteristic of the device under test, in response to a control signal provided by the test head. By controlling the measurement arrangement via the test head, no additional equipment or hardware may be needed, in order to determine the beamforming characteristic. Therefore, determination of the beamforming characteristics of the device under test may be performed with low costs.

According to further embodiments of the disclosure, the measurement arrangement comprises one or more control modules and the one or more control modules are configured to control the actuator. In addition or alternatively, the antenna is configured to provide a plurality of measurement signals, wherein the one or more control modules are configured to control a selection of a measurement signal of the plurality of measurement signals of the antenna. For example, based on a test cycle, the one or more control modules may be configured to coordinate the manipulation of the position of the antenna, relative to the device under test, and a corresponding selection of a measurement signal of the antenna in order to provide a characteristic information on a beamforming characteristic of the device under test.

According to further embodiments of the disclosure, test head comprises one or more, for example, configurable, channel modules for providing a first set of one or more control signals for the measurement arrangement. In addition, the measurement arrangement comprises an interface, wherein the interface is configured to receive the first set of one or more control signals from the test head and wherein the control modules are configured to control the actuator and/or to select the measurement signal of the antenna based on the first set of one or more control signals received from the test head. This may allow for a fully automated testing, reducing costs and testing time.

According to further embodiments of the disclosure, the test head comprises one or more, for example, configurable, channel modules for providing a second set of one or more control signals for the DUT and/or evaluating one or more signals from the DUT. Alternatively or in addition, the test head comprises one or more configurable power supplies for providing one or more supply voltages for the device under test. The test head may perform a plurality of electrical tests on a device under test, for example, in order to verify the functionality of the device under test and may, for example, in addition, provide the device under test with a stimulus causing the device under test to emit a radiation beam that may be measured by the measurement arrangement. By providing, for example additionally, power supplies for the device under test a flexible and compact testing setup may be provided with low complexity and a limited number of hardware.

According to further embodiments of the disclosure, the test head is configured to test, for example electrically, a plurality of devices under test when the devices under test are electrically coupled, or, for example, attached to the load board.

According to further embodiments of the disclosure, the test head is configured to perform a plurality of tests on the plurality of devices under test and the test head is configured to perform one or more tests of the plurality of tests temporally in parallel on a plurality of devices under test. Testing costs and testing time may be reduced or further reduced if a plurality of devices under test is tested in parallel.

According to further embodiments of the disclosure, the test head is configured to provide a test signal for determining a beamforming characteristic of a device under test temporally parallel to a testing of one or more devices under test, for example such that a beamforming test of a given device under test is performed in parallel to an electrical test of one or more other devices under test. One device under test may be chosen, for example, randomly as a sample of a batch for determining its beamforming characteristic while performing in parallel other, for example, electrical tests on the rest of the batch of the one or more devices under test. Therefore, the determination of a beamforming characteristic according to embodiments of the disclosure may be performed as an extension of an electrical test routine.

According to further embodiments of the disclosure, the test head comprises a load board interface and the load board interface is configured to provide one or more signals for the device under test and/or to receive one or more signals from the device under test. In addition or alternatively, the load board interface is configured to establish a connection to the load board, for example directly or via one or more interposer structures. The one or more signals may, for example, comprise one or more supply voltages for the device under test, one or more analog stimulus signals for the device under test, one or more digital stimulus signals for the device under test, radio frequency (RF) and/or millimeter wave (mmWave) signals to/for the device under test. Based on received and provided signals, the test head may evaluate a status or functionality of the device under test. Therefore, any of the before mentioned signals may be used, however, for a specific application any useful signal may be provided, for example with respect to the type of the device under test.

According to further embodiments of the disclosure, the load board interface comprises electrical connections, for example pogo pins, for contacting the load board to establish an electrical connection between the test head and a device under test via the load board. The electrical connections may, for example, be configured to enable a quick attaching and or removing of the load board. In addition, an electrical connection comprising pins may, for example, enable attaching and removing the load board irrespective of whether the measurement arrangement is attached to the load board frame or the test head or not. This may further increase flexibility and reduce testing time, especially if a frequent change of testing routines comprising beamforming determination or no beamforming determination may be necessary.

According to further embodiments of the disclosure, the load board comprises a socket and the socket is configured to accommodate, as a device under test, an antenna in package (AIP) module and to connect the AIP with the load board electrically, for example, via the load board interface. The socket may be configured to keep the device under test in place and may comprise pins in order to provide the electrical connection. Consequently, the device under test may be positioned precisely and may be attached and or removed rapidly.

According to further embodiments of the disclosure, the load board comprises a plurality of sockets and the measurement arrangement is configured to be centered around at least one socket of the plurality of sockets, for example, such that a beamforming characteristic of a device under test, that is attached to the at least one socket, can be determined. This may, for example, be used in order to sample test a device under test with respect to its beamforming characteristics out of a batch of devices under test that may, for example, be tested electrically without a beamforming test. Therefore, such a testing routine may be integrated in existing testing routines, without much effort, with the benefit of providing at least a sample information about antenna characteristics of devices under test of the batch of devices under test.

According to further embodiments of the disclosure, the test head is configured to perform tests on integrated circuits, e.g. to perform integrated circuit level test, for example, for packaged or unpackaged integrated circuits.

### BRIEF DESCRIPTION OF THE DRAWINGS

The drawings are not necessarily to scale, emphasis instead generally being placed upon illustrating the principles of the disclosure. In the following description, various embodiments of the disclosure are described, with reference to the following drawings, in which:

FIG. 1 shows a schematic example of a DFF measurement setup of user equipment (UE) radio frequency (RF) characteristics;

FIG. 2 shows a schematic example of an IFF method (CATR) measurement setup of UE RF characteristics;

FIG. 3 shows, a schematic example of a typical NFTF measurement setup of EIRP (effective isotropic radiated power)/TRP (total radiated power) measurements;

FIG. 4 shows an example of an indirect far field 5G compliant reference measurement setup;

FIG. 5a shows a schematic side view of a measurement arrangement for an automated test equipment according to embodiments of the disclosure;

FIG. 5b shows a schematic side view of a measurement arrangement attached to a load board frame according to embodiments of the disclosure;

FIG. 6 shows an example of a load board with a socket according to embodiments of the disclosure;

FIG. 7 shows an example of a polar plot and an example of a simulation of a three-dimensional beam of a beamforming characteristic of a device under test, according to embodiments of the disclosure;

FIG. 8 shows a schematic side view of a measurement arrangement according to further embodiments of the disclosure;

FIG. 9 shows an example of an enlarged section of the measurement arrangement of FIG. 8 according to further embodiments of the disclosure;

FIG. 10 shows an example of a hardware board of a measurement arrangement according to embodiments of the disclosure;

FIG. 11 shows an example of a first option for device under test load boards according to embodiments of the disclosure;

FIG. 12a shows an example of a second option for device under test load boards according to embodiments of the disclosure;

FIG. 12b shows an example of a third option for device under test load boards according to embodiments of the disclosure;

FIG. 13 shows an example of a prototype of a measurement arrangement according to embodiments of to the disclosure comprising a spacing, between the test head and the load board;

FIG. 14 shows a schematic connection diagram of the automated test equipment and the measurement arrangement, wherein the measurement arrangement comprises, as an example, a beamforming kit, according to embodiments of the disclosure;

FIG. 15 shows an example of an automated test equipment with a standard load board and a schematic example of a corresponding measurement arrangement according to embodiments of the disclosure;

FIG. 16 shows an example of an automated test equipment with a small load board and schematic example of a corresponding measurement arrangement, according to embodiments of the disclosure;

FIG. 17 shows a schematic block diagram of a method for determining a beamforming characteristic of a device under test (DUT), using an automated test equipment (ATE) and a measurement arrangement, according to embodiments of the disclosure;

FIG. 18 shows an example of a measurement arrangement according to embodiments of the disclosure with an absorptive structure; and

FIG. 19 shows an example of a measurement arrangement according to embodiments of the disclosure with a calibration reference antenna.

### DETAILED DESCRIPTION OF THE DISCLOSURE

Equal or equivalent elements or elements with equal or equivalent functionality are denoted in the following description by equal or equivalent reference numerals even if occurring in different figures.

In the following, a plurality of details is set forth to provide a more thorough explanation of embodiments of the present disclosure. However, it will be apparent to those skilled in the art that embodiments of the present disclosure may be practiced without the specific details. In other instances, well-known structures and devices are shown in block diagram form rather than in detail in order to avoid obscuring embodiments of the present disclosure. In addition, features of the different embodiments described hereinafter may be combined with each other, unless specifically noted otherwise.

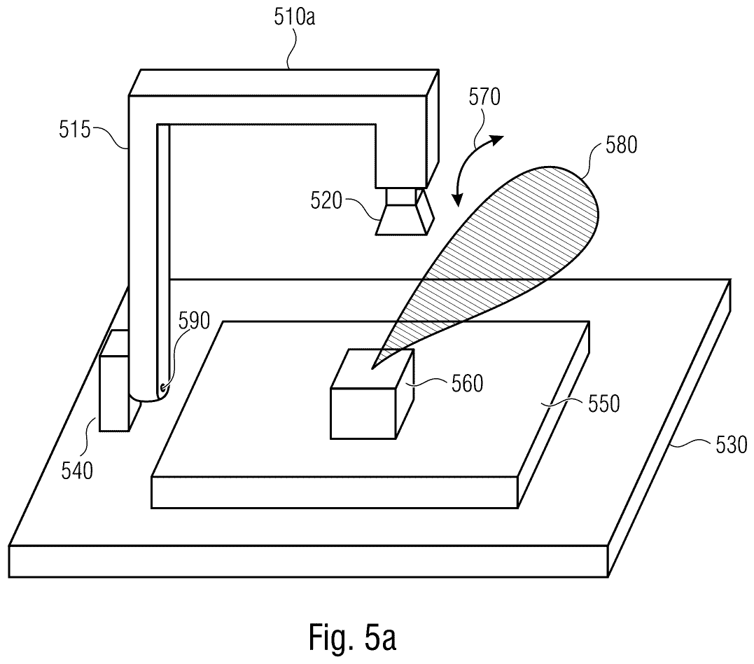

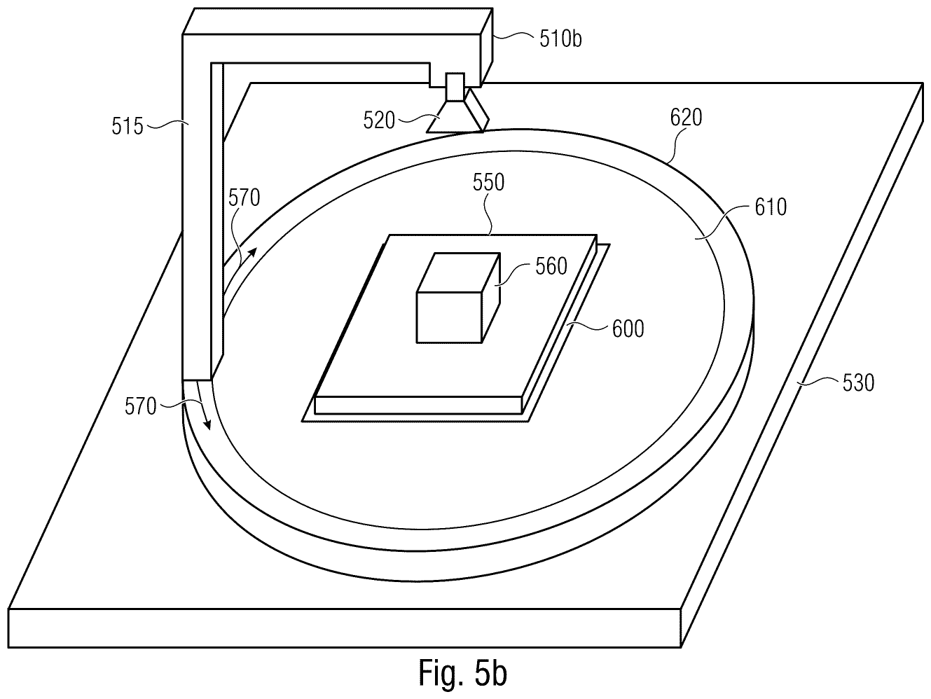

FIG. 5a shows a schematic side view of a measurement arrangement for an automated test equipment according to embodiments of the disclosure. FIG. 5a shows a measurement arrangement 510a that is adapted to carry a measurement antenna 520. Optionally, the measurement antenna 520 may be part of the measurement arrangement, the measurement arrangement optionally comprising a carrier structure 515. The measurement arrangement 510a is configured to be attached to a test head 530 of the automated test equipment. As an optional feature, the measurement arrangement 510a may comprise a mount 540 for attaching the measurement arrangement to the test head. Optionally, as shown in FIG. 5b, the measurement arrangement 510a may be configured to be attached to a load board frame attached to the test head of the automated test equipment. The measurement arrangement may be configured to be attached directly, or indirectly with a load board frame in between the test head and the measurement arrangement, to the test head 530. The measurement arrangement may be configured to be attached removably to the test head or the load board frame, for example, in order to quickly remove or attach the measurement arrangement. Therefore, the measurement arrangement may be a module or an add-on module for the automated test equipment. The test head 530 of the automated test equipment may comprise electrical connections, for example pogo pins, for connecting to a load board 550, for establishing an electrical connection between the test head 530 and a device under test 560 via the load board, for example, when the load board of the automated test equipment is already attached to the test head of the automated test equipment. The measurement equipment 510a is configured to manipulate 570 a position of the antenna 520 relative to the device under test 560, to allow for a determination of the beamforming characteristics 580 of the device under test, when the device under test is coupled to the load board 550, and when the load board 550 is electrically coupled to the test head 530 of the automated test equipment. Optionally, as shown, the measurement arrangement may be configured to rotate around an axis 590 in order to adapt or manipulate or change an elevation of the antenna 520 relative to the device under test 560. In addition or alternatively, the measurement arrangement 510a may be configured to manipulate an azimuth of the antenna relative to the device under test 560.

FIG. 5b shows a schematic side view of a measurement arrangement attached to a load board frame according to embodiments of the disclosure. FIG. 5b shows elements as explained beforehand with FIG. 5a. In addition, measurement arrangement 510b comprises a central part 610 and a ring structure 620 on which a movable carrier structure 515 of the measurement arrangement 510b is arranged. The load board 550 is attached to a load board frame 600 and the measurement arrangement 510b is attached to the load board frame via the central part 610. As shown in FIG. 5b, measurement arrangement 510b is configured to manipulate 570 a position of the antenna relative to the device under test, such that an azimuth of the antenna relative to the device under test is manipulated. The central part 610 may for example, be a circular carrier member, having a circular circumference. In addition, the load board frame 600 is attached to the test head 530 of the automated test equipment.

A measurement setup, e.g. as shown in FIG. 5a or 5b, according to embodiments may comprise a measurement arrangement 510a, b, comprising any or none of the optional features shown in FIG. 5b, and the load board frame 600. In such a setup, the load board frame 600 may be coupled with the load board 550 and attached to the test head. Coupling of the measurement arrangement with the test head may be provided via the load board frame 600, with the measurement arrangement being attached to the load board frame 600.

In addition, as shown in FIG. 5a or 5b, a measurement system, according to embodiments may comprise a test head 530, a load board 550 and a measurement setup, e.g. as explained before, with a measurement arrangement comprising any or none of the optional features shown in FIG. 5b and a load board frame 600.The load board frame 600 may be attached to the test head 530 and the load board 550 may be coupled mechanically to the load board frame 600.

As shown in FIGS. 5a and/or 5b the measurement arrangement 510a, b may be attached to the test head directly or, for example, indirectly via a load board frame which is attached to the test head of the automated test equipment. The device under test 560 may be coupled to the load board which may be electrically connected to the test head. A mechanical connection in between load board and test head may be formed via the load board frame 600. The device under test 560 may then, for example, be stimulated by the test head, for example, via a test program, causing the device under test to act as antenna. The measurement arrangement 510a, b may then be moved, for example, in order to change an elevation and/or an azimuth of an antenna attached to the measurement arrangement or of an antenna which is part of the measurement arrangement in order to allow for a determination of the beamforming characteristics 580 of the device under test 560. Therefore, the measurement arrangement 510a, b may provide a signal to the test head.

Optionally, as shown in FIGS. 5a and 5b, the measurement arrangement 510a, b may be configured to be attached to the test head 530 or the load board frame 600 attached to the test head, when the load board 550 is already electrically coupled to the test head 530 and/or when the load board is already attached to the load board frame. In other words, the measurement arrangement may be a module or an add-on module for an automated test equipment, such that a test assembly may be extended without much effort, for example, without removing load board or even device under test or load board frame and, for example, simply adding the measurement arrangement to the test assembly by attaching the measurement arrangement to the load board frame or the test head.

The measurement arrangement may be attached to the test head or the load board frame. The measurement arrangement may also optionally be supported mechanically by the test head or the load board frame respectively.

As explained before, the measurement arrangement may be configured to manipulate an elevation and/or an azimuth of the antenna relative to a position of the device under test, in order to manipulate the position of the antenna. Therefore, for example, an antenna carrier structure 515 of the measurement arrangement may, for example, be tilted as shown in FIG. 5a and/or rotated around the device under test as shown in FIG. 5b.

Optionally, the measurement arrangement 510a, b may comprise an actuator, for example a motor. The motor may be configured to manipulate the position of the antenna relative to the device under test. Optional mount 540, as shown in FIG. 5a, may, for example, comprise such an actuator. In FIG. 5b, an actuator may be integrated in the ring structure 620, configured to rotate the antenna carrier structure 515 around the device under test. Alternatively or in addition to an actuator, the measurement arrangement may comprise means to manipulate the position of the antenna manually, relative to a position of the device under test.

In order to determine the beamforming characteristic of the device under test, the measurement arrangement may be configured to provide a measurement information. The measurement information may comprise an information about a beamforming characteristic 580, for example, in response to an electric stimulus of the test head. The beamforming characteristic may be determined by a comparison between the measurement information and an information about the electric stimulus.

Optionally, as shown in FIG. 5b, the measurement arrangement may comprise, in the central part 610, an opening for the load board frame. As shown in FIG. 5b, the measurement arrangement may be attached and/or set upon an outer edge of the load board frame, for example via the central part 610. Therefore, the measurement arrangement may be easily attachable and removable, without removing the load board and a device under test. In other words, the central part 610 may be configured to be attached to the load board frame. Optionally, the central part may be configured to be attached to the test head, for example, directly.

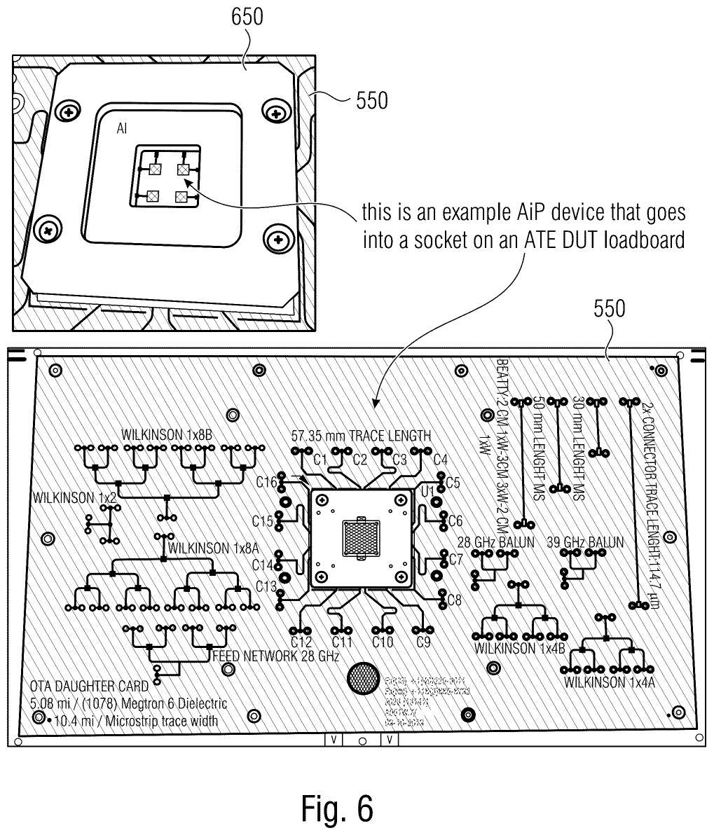

FIG. 6 shows an example of a load board with a socket according to embodiments of the disclosure. Load board 550 may comprise a socket 650, wherein the socket is configured to accommodate the device under test. The device under test may, for example, be an antenna in package (AIP) module. In addition, according to the implementation example of FIG. 6, the socket may be configured to connect the AIP with the load board 550 electrically, for example, via a load board interface. In other words, FIG. 6 may show an example antenna in package device (AiP) that goes into a socket 560 on an automated test equipment device under test load board 550.

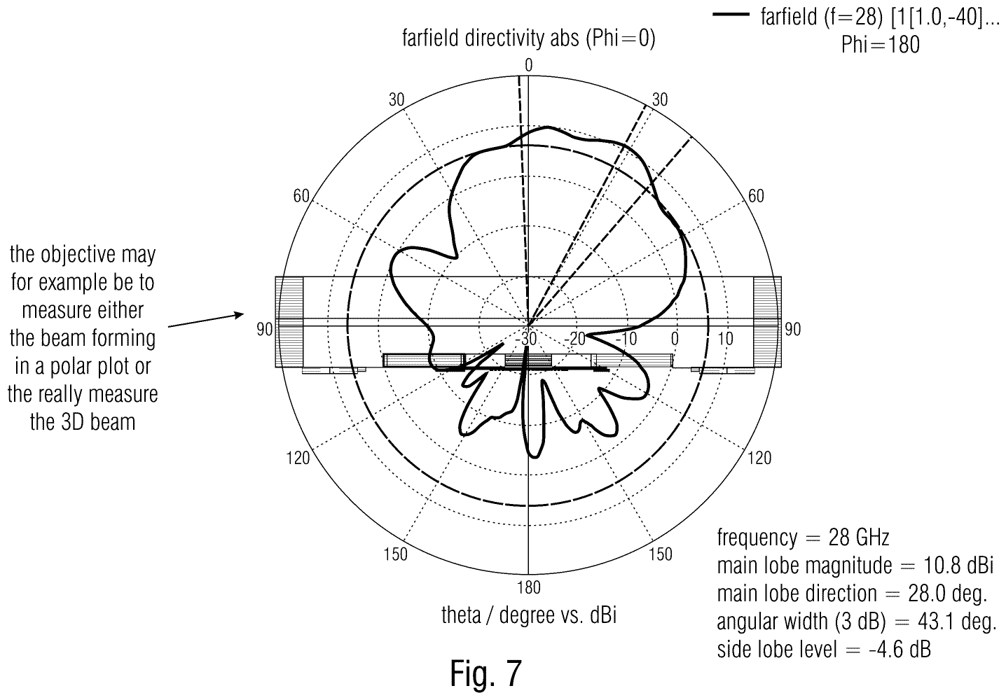

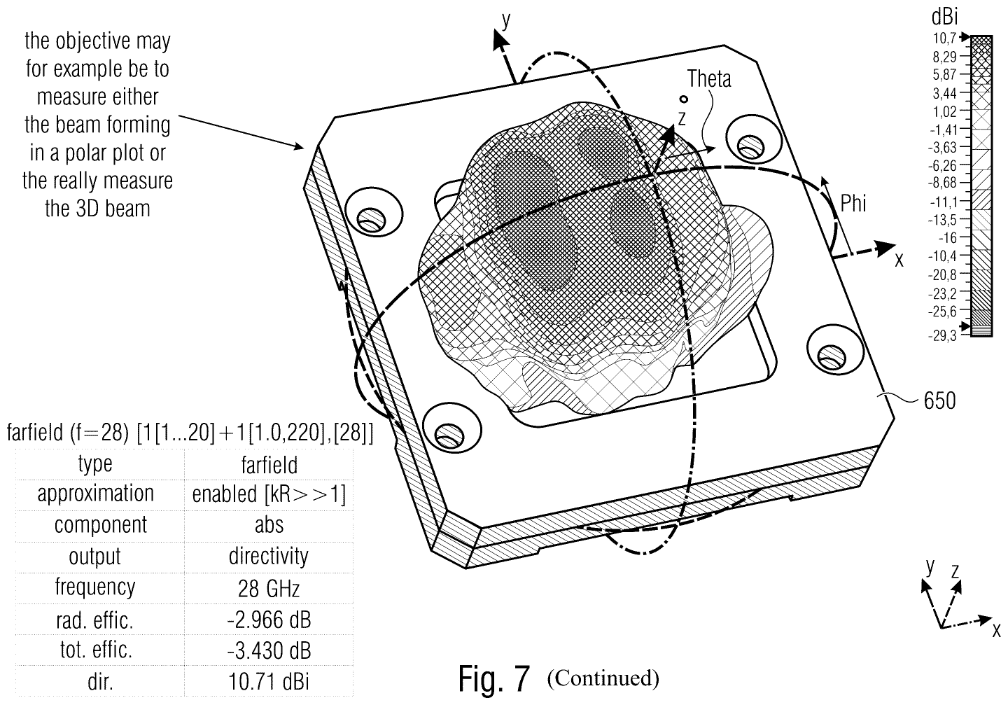

FIG. 7 shows an example of a polar plot and an example of a simulation of a three-dimensional beam of a beamforming characteristic of a device under test, according to embodiments of the disclosure. The objective, according to embodiments, may, for example, be to measure either the beamforming in a polar plot or, for example, to measure the 3D beam of the device under test. Such a measurement may comprise, for example alternatively or in addition to the determination of a plot according to FIG. 7, a determination of a main lobe magnitude, a main lobe direction, an angular width, e.g. a 3 dB angular width and/or a side lobe level, for example at a certain frequency.

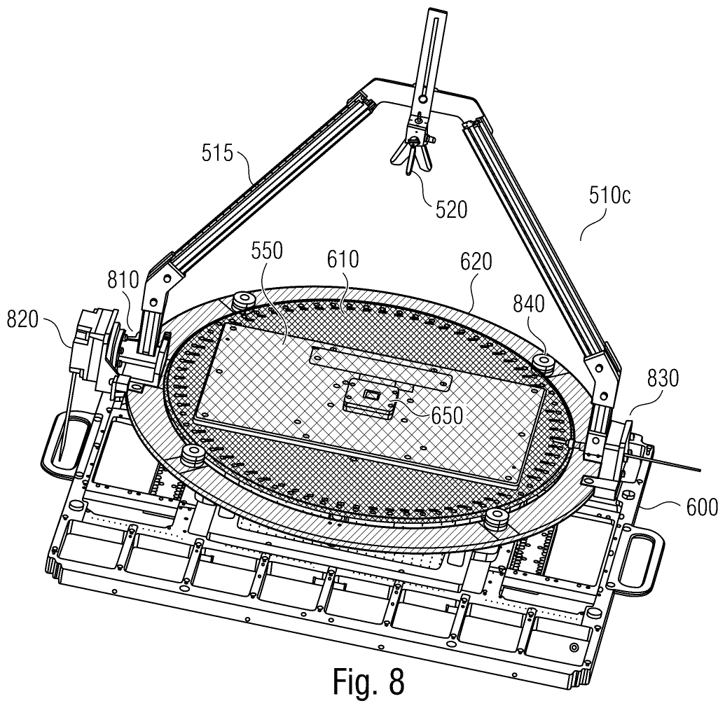

FIG. 8 shows a schematic side view of a measurement arrangement according to further embodiments of the disclosure. The measurement arrangement 510c comprises a central part 610 which is configured to be attached to a load board frame 600. Furthermore, the measurement arrangement comprises a ring structure 620 around the central part. In addition, the measurement arrangement 510c comprises a carrier structure 515 which is adapted to carry an antenna 520. Optionally, the antenna 520 may be part of the measurement arrangement 510c. Optionally, as shown, the measurement arrangement comprises a first rotary joint 810 to which the carrier structure 515 is attached. A load board 550 is attached to the load board frame 600 and the load board 550 comprises a socket 650. In FIG. 8, a test head is not shown.

In order to determine a beamforming characteristic of a device under test, that may be attached to the socket 650, the test head may stimulate the device under test electrically. To determine the beamforming characteristics of the stimulated device under test, the ring structure 620 is configured to be rotatable around the central part 610 and the first rotary joint 810 is configured to allow for a manipulation of an elevation of the carrier structure 515 relative to the central part 610 via a rotation of the carrier structure 515. Therefore, an azimuth and/or an elevation of the antenna relative to the device under test may be manipulated in order to determine a measurement information, for example, to provide a beamforming information according to FIG. 7.

Optionally, as shown in FIG. 8, an opening, e.g. a rectangular opening, of the measurement arrangement 510c, for example, as shown in the central part 610, is formed for the load board frame, such that the measurement arrangement 510c can be attached to and/or removed from the test head and/or the load board frame respectively, while the load board is attached to the load board frame which is attached to the test head. Therefore, the central part may comprise a circular outer boundary or a circular circumference to be set upon the load board frame. This may provide a mechanical connection or a mechanical support between central part and load board frame.

Optionally, the ring structure 620 and the central part 610 may be arranged in the same plane or in two planes that are parallel to each other. According to further embodiments, other orientations or alignments in between central part 610 and ring structure 620 are possible. However, it may be beneficial to align these elements in a parallel manner in order to calibrate an elevation of the carrier structure 515 easily. Otherwise, a non-parallel alignment between central part and ring structure may have to be considered for each measurement.

Optionally, as shown in FIG. 8, the measurement arrangement may comprise a secondary rotary joint 830, wherein the first rotary joint 810 and the second rotary joint 830 are attached to opposite sides of the ring structure 620. In addition, the first and second rotary joints may be arranged, such that they comprise a common rotation axis, wherein the rotation axis and a normal vector of the plane of the central part 610 and/or of the plane of the ring structure 620 may be orthogonal or at least approximately orthogonal, for example, with a tolerance of less than 0.01 degree or of less than 0.1 degree, of less than 1 degree or of less than 5 degrees. In addition, as shown, the carrier structure 515 may be attached to the first and second rotary joint, wherein the first and second rotary joints are configured to allow for a manipulation of an elevation of the carrier structure 515 relative to the central part or the device under test, respectively, via a rotation of the carrier structure 515 around the common rotation axis of the first and second rotary joint. With a second rotary joint 830 attached to the carrier structure 515, a stiffness of the measurement arrangement may be increased, such that the measurement arrangement, and especially the carrier structure 515, may not bend easily and therefore may be more robust and may provide precise measurements. Optionally, the measurement arrangement 510c may be configured to center the antenna 520, when attached to the carrier structure 515 or when part of the carrier structure 515, over the device under test or the device test position or the device under test socket. This may provide for an easier calibration and zeroing of the measurement angles of the beamforming characteristics. Therefore, a centering of the antenna over the device under test may be achieved when an angle in between a carrier structure 515 and a load board is 90 degrees.

Optionally, as shown in FIG. 8, the ring structure 620 may comprise a plurality of bearing elements 840. Mechanical support of the ring structure may be provided by the central part via the bearing elements, such that the ring structure 620 can rotate around the central part 610. As mentioned before, the central part may be attached to an edge or an outer circumference of the load board frame 600. The bearing elements may be actuated and may be used in order to set an azimuth of the antenna relative to the device under test. As another optional feature, the measurement arrangement may comprise a second actuator, not shown in FIG. 8, for example, underneath the ring structure that is configured to rotate the ring structure 620 around the central part 610, for example, via actuating the bearing elements.

In addition, FIG. 8 shows, as optional feature, as explained before, the measurement arrangement 510c comprising an actuator 820, for example a motor. The motor may be configured to manipulate the position of the antenna relative to the device under test or socket 650 respectively.

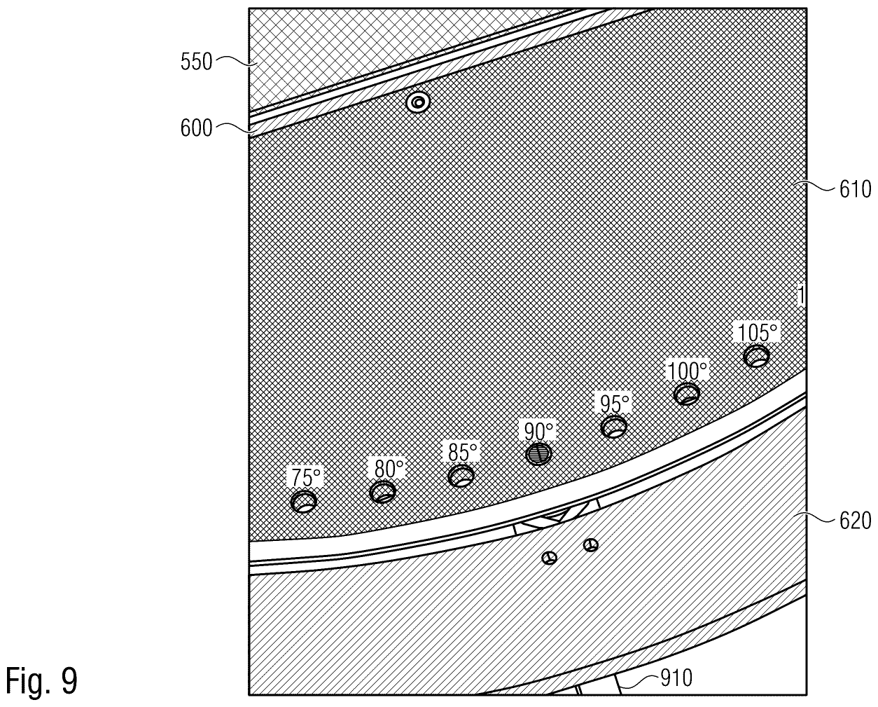

FIG. 9 shows an example of an enlarged section of the measurement arrangement of FIG. 8 according to further embodiments of the disclosure. FIG. 9 shows an optional scale for manipulating, for example, manually, e.g. with an optionally shown lever 910, an azimuth of the antenna, relative to the device under test. In an embodiment with an actuated manipulation of the azimuth such a scale and/or such a lever 910 may, for example, not be present.

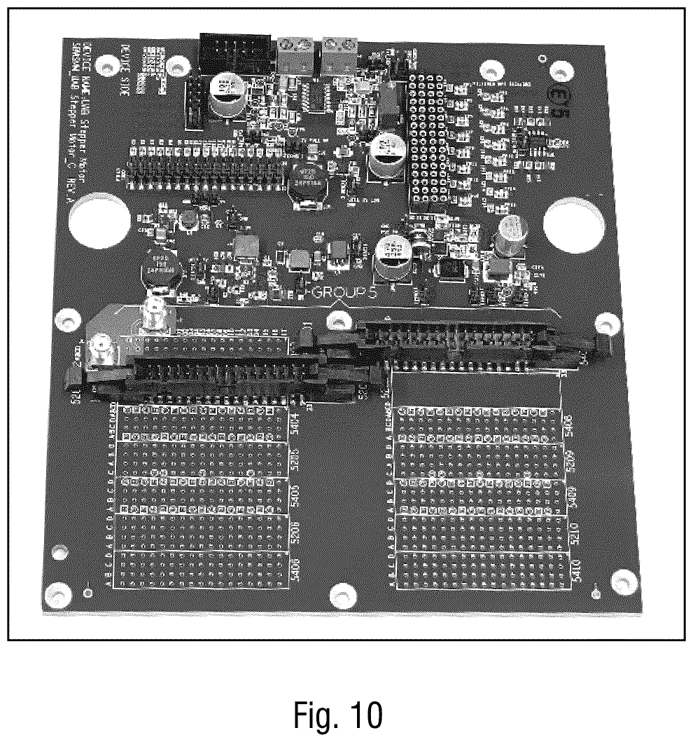

FIG. 10 shows an example of a hardware board of a measurement arrangement according to embodiments of the disclosure. The measurement arrangement may comprise a specialized board in order to provide its functionality, for example, in order to enable a manipulation of the azimuth and/or elevation of the carrier structure, relative to the device under test and/or to provide a measurement information about a beamforming characteristic of a device under test.

FIGS. 8, 9 and 10, may optionally show one implementation example of embodiments of the disclosure. In this implementation example a mechanical setup 510c was developed that is mechanically compatible with the target ATE system so that it is easy to install and remove without having to remove the DUT Load board 550. In this implementation, a motor 820 automatically moves the antenna for different elevations allowing to perform a polar antenna measurement. The user can choose the azimuth manually with a lever 910 as shown e.g. in FIG. 9. The azimuth could also be motorized. By combining in the SW, e.g. software, the elevation measurement at different azimuths it may be, or is possible to generate the 3D Beam forming, e.g. as shown in FIG. 7. The motor control may be or is done completely from the ATE Software and Hardware. A specialized board was developed for this, and may hence, for example be used according to embodiments.

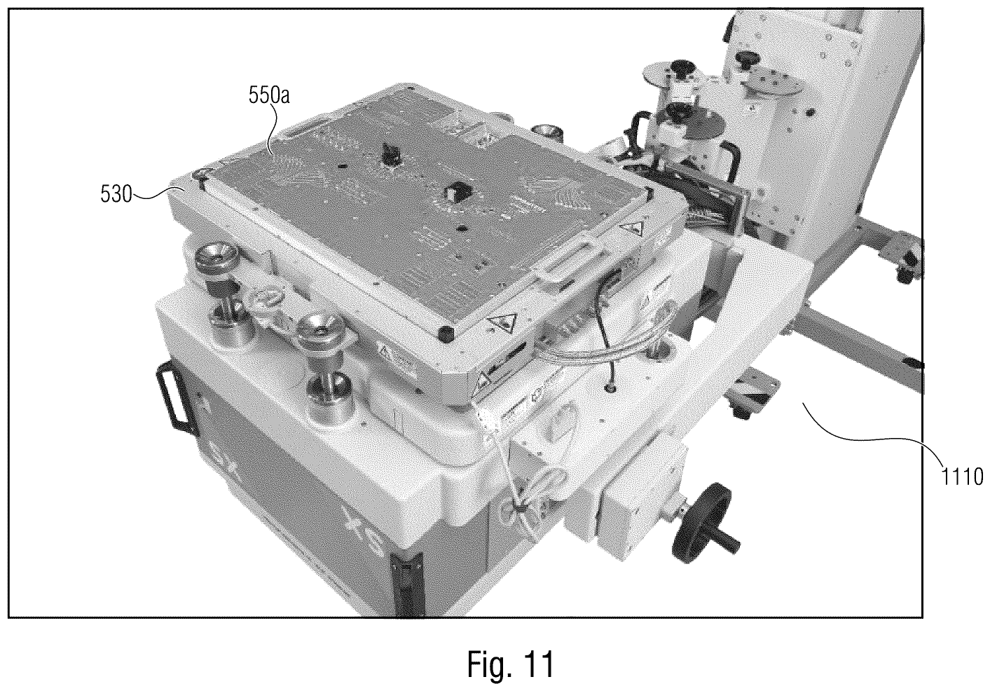

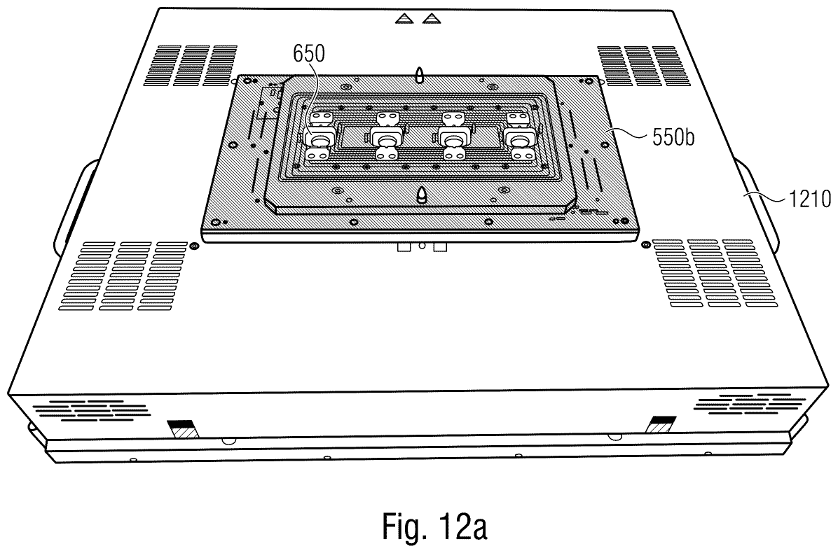

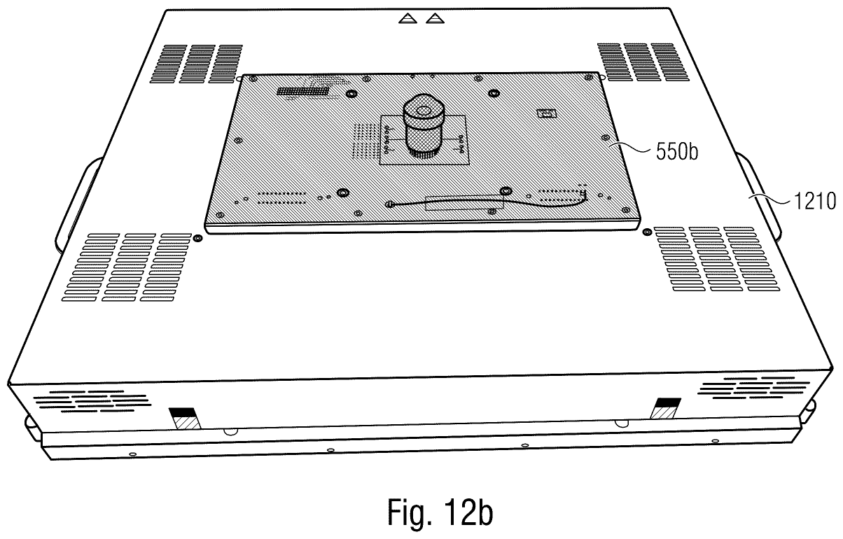

FIGS. 11, 12a and 12b show examples of different options for device under test load boards according to embodiments of the disclosure. FIG. 11 shows an automated test equipment 1110 with a test head 530 and a load board 550a which may, for example, be a standard large load board. FIG. 12a shows a spacing in the form of a garage space 1210, provided by the load board frame (not visible), and a load board 550b, which may, for example, be a small or smaller load board, e.g. smaller than the load board 550a shown in FIG. 11, with a plurality of sockets 650. The garage space 1210 may optionally be covered with a casing or cover, as shown in FIG. 12a. Garage space 1210 may go, or may, for example, be arranged on top of a test head. In other words, garage space 1210 of FIGS. 12a and 12b may go on top of test head 530 in FIG. 11, e.g. instead of the large load board 550a, for example, therefore with the smaller load board 550b as shown in FIG. 12a. The garage space 1210 may, for example, be configured to store additional components, for example large components and/or custom components, e.g. components specifically manufactured for distinct applications. The load boards 550a, b may, for example, allow storage of small size components, therefore additional space may be provided underneath the casing of garage space 1210. In other words, additional large custom components can be added by the user. The load board may allow the user to add small size components but the garage space below the load board 550b in the FIGS. 12a and 12b examples may allow for very large components, even a full compact measurement instrument. A load board 550 may comprise a plurality of sockets, e.g. as shown with load board 550b in FIG. 12a, and therefore a plurality of devices under test. In addition, the measurement arrangement may optionally be configured to be centered around at least one socket of the plurality of sockets, for example, such that a beamforming characteristic of a device under test, that is attached to the at least one socket, may be determined. Hence, as an example, the measurement arrangement may be centered above one of the sockets a shown in FIG. 8. Optionally, a load board with or without a socket may be configured to enable a testing of integrated circuits. In other words, the measurement arrangement may optionally be configured to perform integrated circuit level tests. FIG. 12b shows another example of a garage space 1210 with a casing, e.g. cover, and a load board 550b, e.g. the same small load board as shown in FIG. 12a but without the optional plurality of sockets, according to embodiments of the disclosure.

Optionally, usage of the smaller load boards 550b, for example load boards as shown in FIGS. 12a and 12b, may enable the usage of the garage space below. The garage space, for example with a casing, may be arranged below the load board on top of the test head. The garage space may be used advantageously with a small load board.

In general, according to embodiments of the disclosure the test head 530 may be configured to test, for example electrically, a plurality of devices under test when the devices under test are electrically coupled or, for example, attached to the load board. For a plurality of devices under test, the load board may comprise a plurality of sockets, for example, as shown in FIG. 12a.

In addition, the test head 530 may be configured to perform a plurality of tests on the plurality of devices under test. In addition, the test head may be configured to perform one or more tests of the plurality of tests temporally in parallel on a plurality of devices under test. Parallelization of testing may reduce testing time and therefore testing costs.

According to further embodiments, the test head 530 may be configured to provide a test signal for determining a beamforming characteristic of a device under test temporally parallel to a testing of one or more devices under test, for example, such that a beamforming test of a given device under test is performed in parallel to an electrical test of one or more devices under test. For example, one socket of the load board may be centered under the antenna of the measurement arrangement 510c when the carrier structure and central part are arranged in 90 degrees or at least approximately 90 degrees, such that the device under test may be tested as a sample of a batch of devices under test, the batch being attached to the sockets of the load board and the batch being tested electrically.

Optionally, the test head 530 may comprise a load board interface, e.g. underneath load boards 550a, b in FIGS. 11, 12a and 12b, and the load board interface may be configured to provide one or more signals for the device under test and/or to receive one or more signals from the device under test. The signals may, for example, be supply voltages and/or one or more analog stimulus signals, one or more digital stimulus signals, radio frequency and/or millimeter wave signals. In addition or alternatively, the load board interface may be configured to establish a connection to the load board 550a, b, for example, directly or via one or more interposer structures. In other words, according to embodiments of the disclosure, the test head 530 may be configured to provide any kind of useful signal in order to test the device under test and/or to determine a beamforming characteristic of the device under test and such a signal may be provided to the device under test via a load board interface. Optionally, the load board interface may comprise electrical connections, for example, such as pogo pins, for contacting the load board to establish an electrical connection between the test head and the device under test via the load board. A load board interface with pins may be beneficial for a quick attaching and removing or releasing of the load board from the load board interface and the load board frame respectively. Therefore, testing with different load boards may be performed in quick succession.

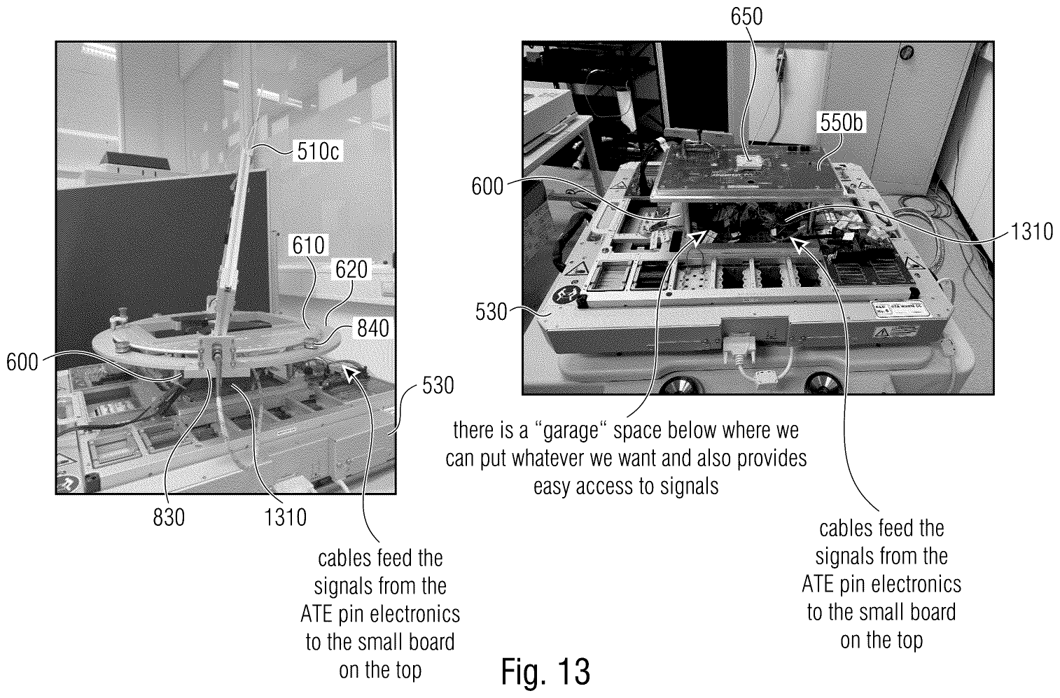

FIG. 13 shows an example of a prototype of a measurement arrangement according to embodiments of the disclosure comprising a spacing 1310, for example a garage space, between the test head and the load board. In comparison to FIGS. 12a, 12b, spacing 1310 is not covered with a casing or cover. FIG. 13 shows two test heads 530 with load board frames 600, wherein on the left-hand side a measurement arrangement 510c is attached to a load board frame 600 without a load board and on the right-hand side a load board frame 600, with a load board attached to it, but without measurement arrangement, is shown. According to embodiments of the disclosure, the load board frame 600 may be configured to allow for a routing of one or more cables for feeding signals from the test head 530 to the load board 550b, and/or to allow for a routing of one or more cables for guiding signals from the load board 550b to the test head 530 and/or to allow for a routing of one or more cables from the test head 530 to the measurement arrangement 510c. Hence, cables may feed the signals from the automated test equipment pin electronics to the load board 550b, for example a small board on the top. In addition to providing a garage space where any necessary elements or equipment or additional components may be put or stored, easy access to the signals, cables or elements may also be provided.

Optionally, the test head 530 may be configured to perform one or more electrical tests on the device under test, for example, under the control of a test program. The electrical tests may, for example, be executed in the absence of the antenna or may not use the antenna.

In addition, for example, when electrically connected to the test head 530, the measurement arrangement may be configured to be controlled by the test head. Consequently, a closed testing loop may be provided.

As another optional feature, the measurement arrangement 510c may be configured to manipulate the position of the antenna and/or to provide a measurement information for determining the beamforming characteristic of the device under test, in response to a control signal provided by the test head 530.

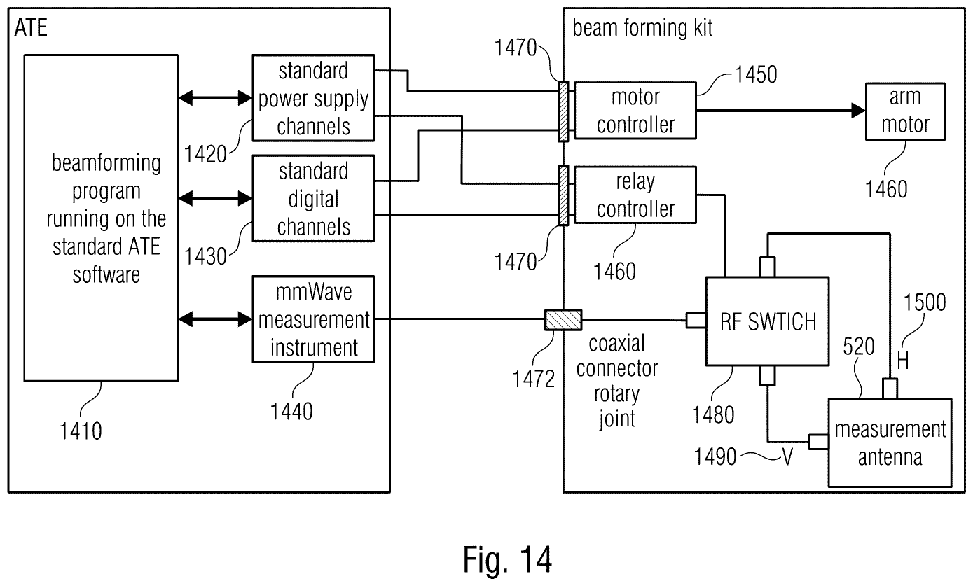

FIG. 14 shows a schematic connection diagram of the automated test equipment and the measurement arrangement, wherein the measurement arrangement comprises, as an example, a beamforming kit, according to embodiments of the disclosure. The automated test equipment, or for example a test head or an ATE system test head, comprises a beamforming program 1410 running on the standard automated test equipment software. However, this may be any testing program suitable, for example, comprising electrical tests and/or beamforming tests. The program may be configured to test a plurality of devices under test electrically and a sample or a set of the plurality of devices under test with regard to its beamforming characteristics. The automated test equipment, or for example a test head or an ATE system test head, further comprises standard power supply channels 1420, standard digital channels 1430 and millimeter wave measurement instruments 1440. The program 1410 is configured to interact with the channels and the measurement instrument 1420, 1430, 1440. These channels may be provided by the test head and may optionally be configurable, for example, for providing a first set of one or more control signals for the measurement arrangement. The measurement arrangement may optionally comprise a motor controller 1450, for example, in the case that the measurement arrangement comprises an actuator, and a relay controller 1460. As another optional feature, the measurement arrangement comprises an arm motor 1460 which may be configured to manipulate an elevation of the carrier structure in order to manipulate an elevation of the antenna relative to the device under test. In order to receive the before mentioned control signals from the test head, the measurement arrangement may comprise an interface 1470 which may be configured to receive said first set of one or more control signals from the test head. In addition, the measurement arrangement may comprise a coaxial connector rotary joint 1472, which may be part of the interface 1470 in order to interact with the millimeter wave measurement instrument 1440. The measurement arrangement may optionally comprise an RF switch 1480, receiving signals from the relay controller 1460 and the coaxial connector rotary joint 1472. As explained before, the measurement arrangement, e.g. beamforming kit, may comprise the measurement antenna 520. In general, the measurement antenna 520 may be configured to measure horizontal (H) and vertical (V) components (1490 vertical component, 1500 horizontal component) of electromagnetic waves. In other words, H is horizontal polarization and V is vertical Polarization. Electromagnetic waves can be polarized and, according to embodiments, the polarization may be measured, e.g. horizontal and vertical components of the polarization can be measured. Hence, the RF switch 1480 may receive the measured components H, V and may, for example, provide them to the ATE, e.g. via relay controller 1460.

In other words, the control modules 1450, 1460 may be configured to control the actuator 1460 and/or to select the measurement signal of the antenna based on the first set of one or more control signals received from the test head.

Yet in other words, the test head may comprise one or more, for example, configurable channel modules 1420, 1430 for providing a second set of one or more control signals from the device under test and for evaluating one or more signals from the device under test and/or the test head may comprise one or more configurable power supplies for providing one or more supply voltages for the device under test.

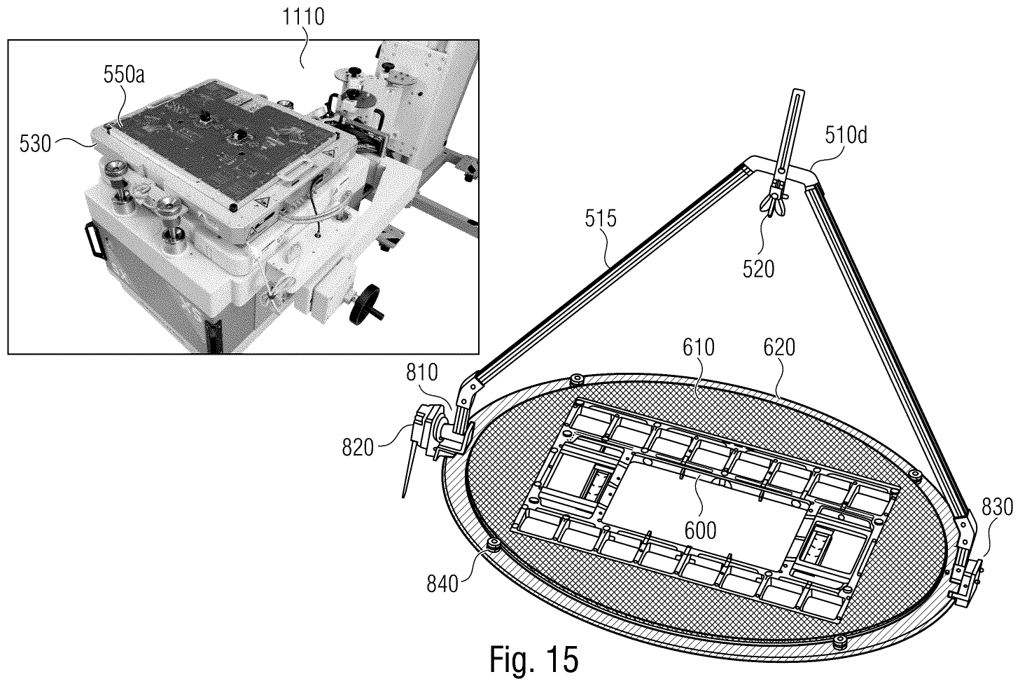

FIG. 15 shows an example of an automated test equipment 1110 with a standard load board 550a, e.g. a large load board, and a schematic example of a corresponding measurement arrangement 510d according to embodiments of the disclosure for determining a beamforming characteristic of a device under test for usage with the standard load board. In this example, the load board frame 600 may not provide for a garage space. Measurement arrangement 510d may be arranged upon the load board frame of load board 550a shown on top of the ATE 1110, where the test head 530 is also shown.

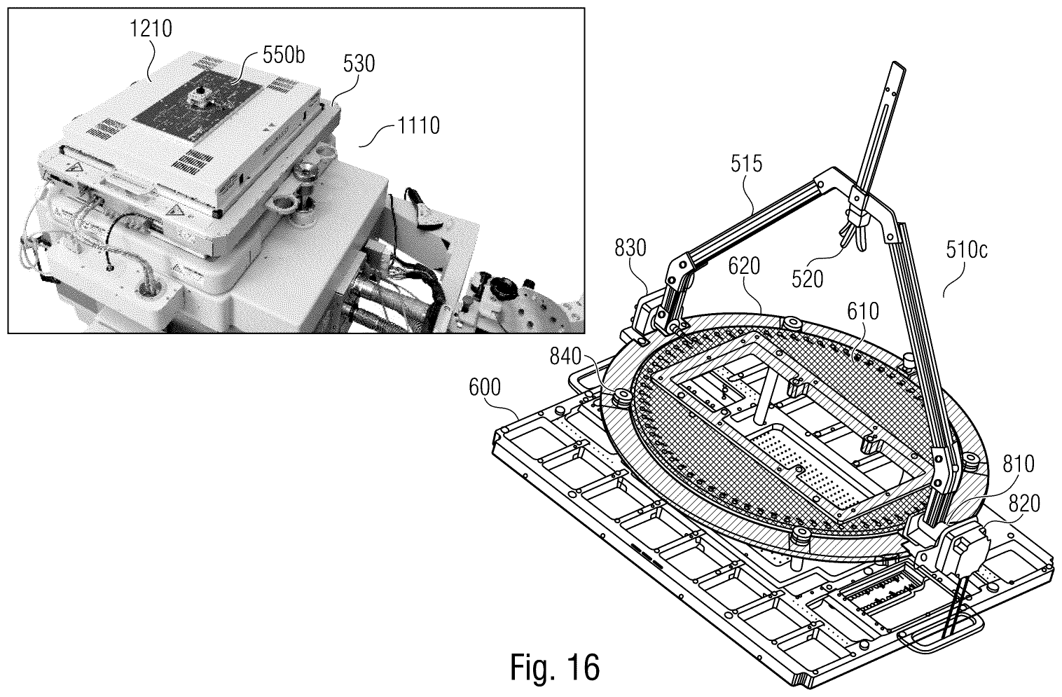

FIG. 16 shows an example of an automated test equipment 1110 with a small load board 550b and a schematic example of a corresponding measurement arrangement 510c according to embodiments of the disclosure. A measurement setup may comprise the measurement arrangement 510c and the load board frame 600. In this example, the load board frame 600 may provide for a garage space. In the picture on the top left of FIG. 16, the automated test equipment 1110 comprises a test head 530. On top of the test head 530 the garage space 1210 is arranged. Load board frame 600 may provide for the garage space 1210. In this example, the spacing provided by the load board frame is covered with a casing providing the garage space 1210. On top of the load board frame 600, which is not shown in the top left picture since it is arranged underneath the casing of the garage space 1210, the load board 550b is arranged.

In general, embodiments according to the disclosure may comprise a cover, or casing, and the cover or casing may, for example, be configured to cover a spacing provided by the load board frame, in order to provide a covered garage space, for storing additional components, for example for testing the device under test and/or for a routing and/or storing of cables.

On the load board frame 600, with the load board 550b on top, the measurement arrangement 510c may be arranged, e.g. attached to the load board frame (that may be covered by the casing), as shown in the schematic view in the bottom right corner of FIG. 16, but, for example, with load board 550b attached to the load board frame (as shown in the top left picture), centered in the central part of the measurement arrangement 510c. According to embodiments of the disclosure, a small load board with garage space may be used. An example of the setup as shown in the top left corner of FIG. 16 without the cover may be shown on the right-hand side of FIG. 13.

FIGS. 15 and 16 may show further implementation options according to embodiments of the disclosure.

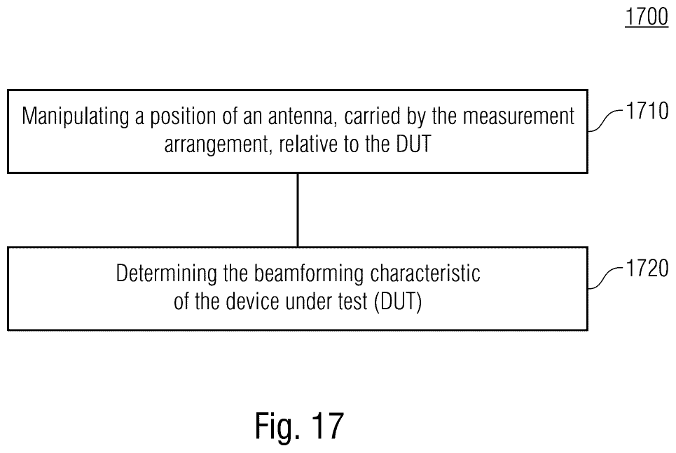

FIG. 17 shows a schematic block diagram of a method for determining a beamforming characteristic of a device under test (DUT), using an automated test equipment (ATE) and a measurement arrangement, according to embodiments of the disclosure. Method 1700 comprises manipulating (1710) a position, e.g. an elevation and/or an azimuth, of an antenna, carried by the measurement arrangement, relative to the DUT, while the DUT is coupled to a load board, and while the load board is electrically coupled to a test head of the ATE and wherein the measurement arrangement is attached to the test head of the ATE or to a load board frame attached to the test head of the ATE. The method further comprises determining (1720) the beamforming characteristic of the device under test (DUT), e.g. based on signals from the antenna.

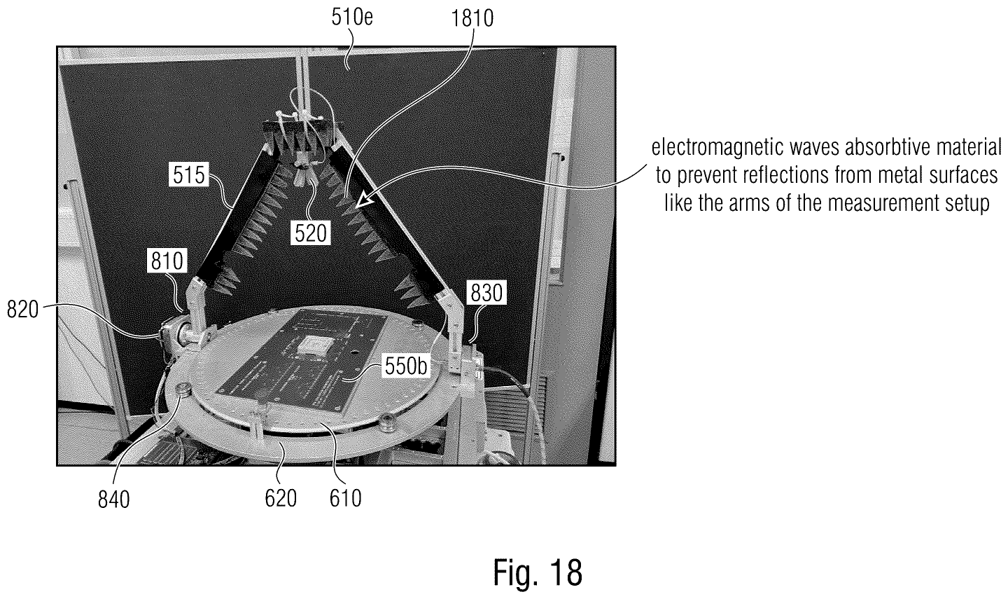

FIG. 18 shows an example of a measurement arrangement according to embodiments of the disclosure with an absorptive structure. In addition to the elements explained before, the measurement arrangement 510e shown in FIG. 18 comprises an absorptive structure 1810. As an optional feature, absorptive structure 1810 is arranged on the carrier structure 515. Electromagnetic waves absorptive material may prevent reflections from metal surfaces like the arms of the measurement setup. To improve the performance of the measurement setup, e.g. beamforming measurement setup, special electromagnetic absorptive materials can be added to the metal surfaces to prevent the reflection of electromagnetic waves from metal surfaces interfering with the antenna beamforming measurements.

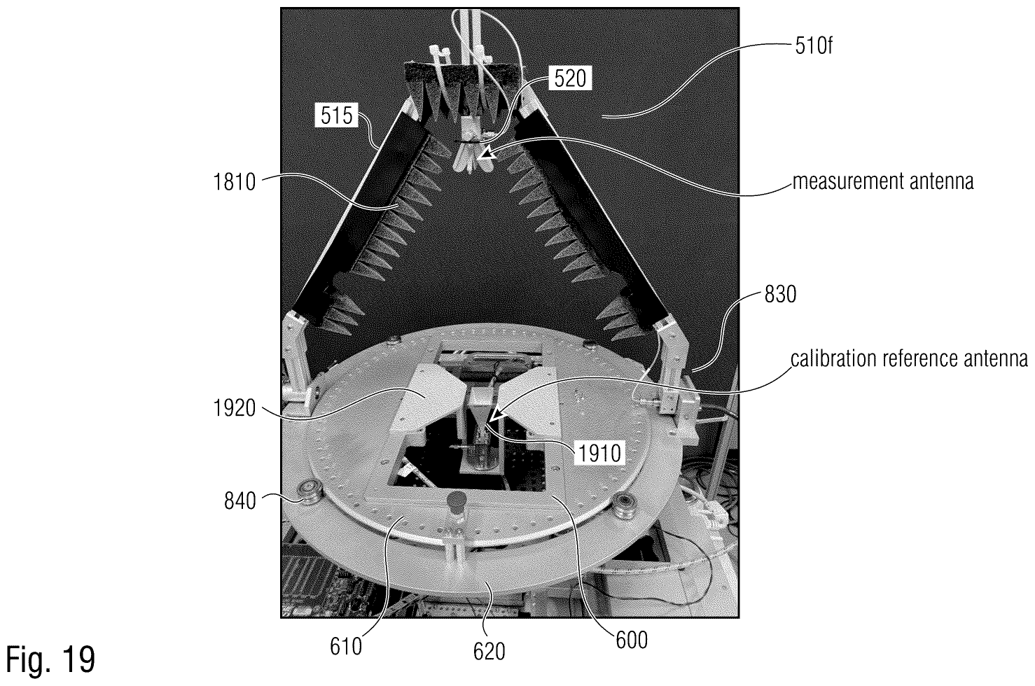

FIG. 19 shows an example of a measurement arrangement according to embodiments of the disclosure with a calibration reference antenna. In addition to the elements explained before, measurement arrangement 510f shown in FIG. 19 comprises a calibration reference antenna 1910 configured to provide a reference signal for a calibration of the measurement antenna 520. As shown, the calibration reference antenna may, for example, be arranged in the center of the central part 610 of the measurement setup. As another optional feature, the reference antenna 1910 comprises a mount 1920 that is attached to the load board frame 600. However, the reference antenna may be attached to any suitable structure, e.g. the central part 610. For calibrating the beamforming setup, the reference antenna 1910 with a known calibrated gain can or may, for example, be attached to the center of the measurement setup, for example, instead of the load board and DUT for calibration. As explained before, calibration of the measurement antenna 520 may be performed with low time effort. As an example, measurement arrangement 510f may be kept attached to the load board frame 600, which may be attached to a test head. The load board, e.g.

comprising a device under test may be removed, in order to attach the reference antenna 1910, e.g., with optional mount 1920 to the load board frame 600 and/or to the central part 610. After performing the calibration, the reference antenna 1910 may be removed and the load board may be reattached.

In general, embodiments according to the disclosure comprise an approach to integrate a far-field antenna beamforming measurement setup, or for example measurement arrangement, on a commercial ATE system.

The main idea according to embodiments may be, or for example is, to have a far-field measurement setup that can be easily attached and removed from a commercial ATE system and allows to measurement the complete beam shape of an antenna in package (AiP) module. The entire measurement may be controlled by the ATE software.

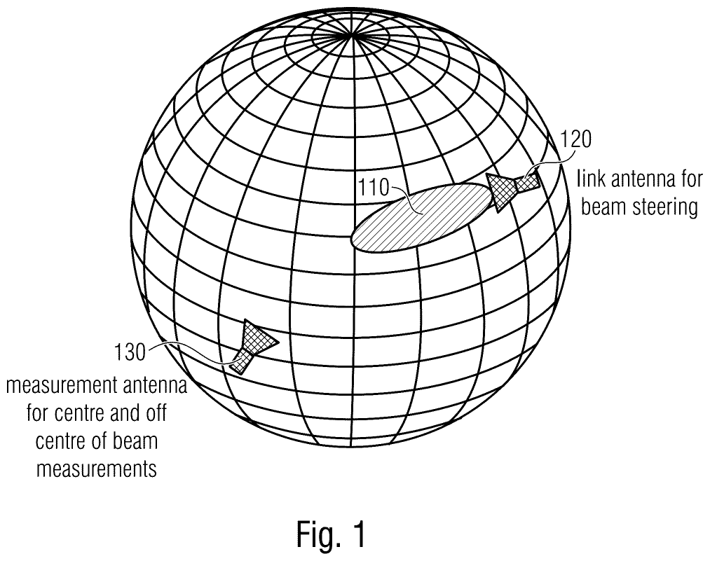

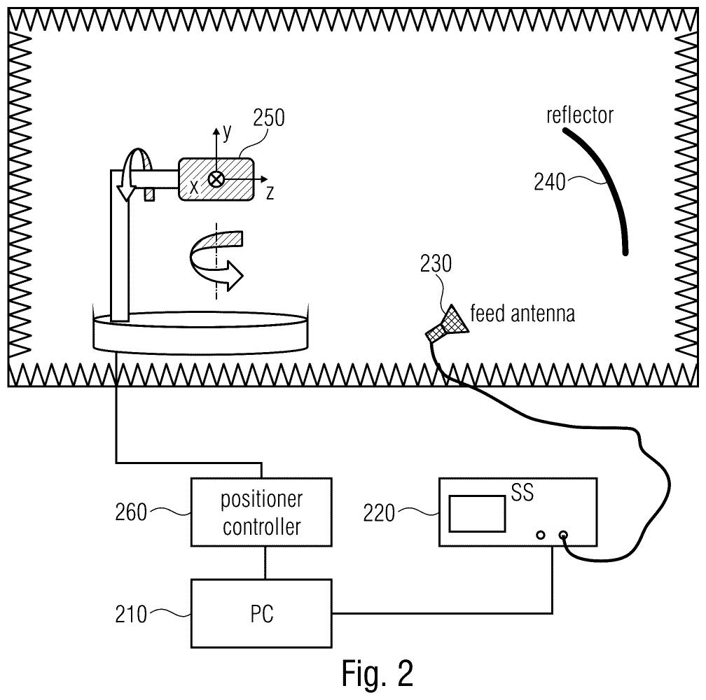

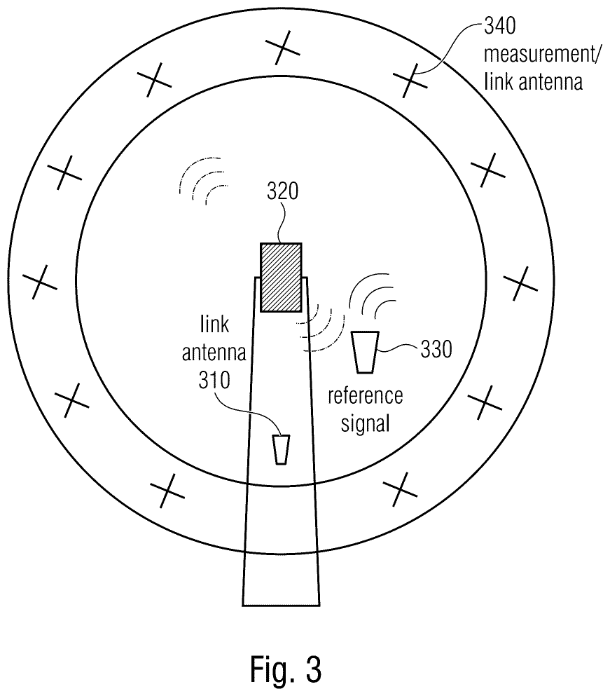

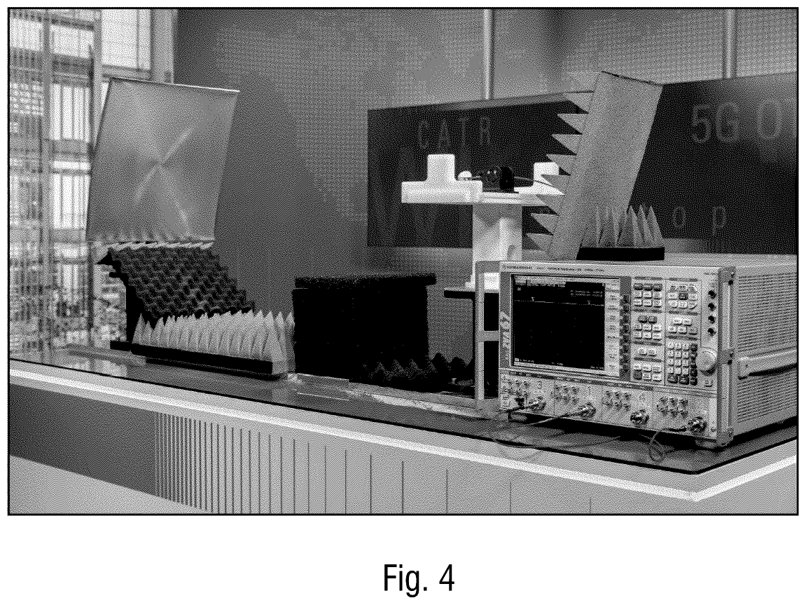

The advantage of this setup, or for example a measurement arrangement according to embodiments, compared to a standard measurement setup, e.g. as shown in FIGS. 1-4 is that it may or even will use the exact same ATE setup including test. Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

Depending on certain implementation requirements, embodiments of the disclosure can be implemented in hardware or in software. The implementation can be performed using a digital storage medium, for example a floppy disk, a DVD, a CD, a ROM, a PROM, an EPROM, an EEPROM or a FLASH memory, having electronically readable control signals stored thereon, which cooperate (or are capable of cooperating) with a programmable computer system such that the respective method is performed.

Some embodiments according to the disclosure comprise a data carrier having electronically readable control signals, which are capable of cooperating with a programmable computer system, such that one of the methods described herein is performed.

Generally, embodiments of the present disclosure can be implemented as a computer program product with a program code, the program code being operative for performing one of the methods when the computer program product runs on a computer. The program code may for example be stored on a machine-readable carrier.

Other embodiments comprise the computer program for performing one of the methods described herein, stored on a machine-readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods may be performed by any hardware apparatus.

While this disclosure has been described in terms of several embodiments, there are alterations, permutations, and equivalents which fall within the scope of this disclosure. It should also be noted that there are many alternative ways of implementing the methods and compositions of the present disclosure. It is therefore intended that the following appended claims be interpreted as including all such alterations, permutations, and equivalents as fall within the true spirit and scope of the present disclosure.

1. A measurement arrangement for an automated test equipment (ATE), for determining a beamforming characteristic of a device under test (DUT),
wherein the measurement arrangement is adapted to carry an antenna, and
wherein the measurement arrangement is configured to manipulate a position of the antenna, relative to the DUT, to allow for a determination of the beamforming characteristic of the DUT when the DUT is coupled to a load board, and when the load board is electrically coupled to a test head of the ATE; and
wherein the measurement arrangement is configured to be attached to the test head of the ATE or to a load board frame attached to the test head of the ATE.

2. The measurement arrangement according to claim 1, wherein the measurement arrangement is configured to be attached to the test head or the load board frame attached to the test head, when the load board is already electrically coupled to the test head and/or when the load board is already attached to the load board frame.

3. The measurement arrangement according to claim 1, wherein the measurement arrangement is configured to be supported mechanically by the test head or by the load board frame attached to the test head.

4. The measurement arrangement according to claim 1, wherein the measurement arrangement is configured to manipulate an elevation and/or an azimuth of the antenna, relative to a DUT position, in order to manipulate the position of the antenna.

5. The measurement arrangement according to claim 1, wherein the measurement arrangement comprises a central part; and
wherein the measurement arrangement comprises, in the central part, an opening for the load board frame, wherein the central part is configured to be attached to the load board frame.

6. The measurement arrangement according to claim 5, wherein the measurement arrangement comprises
a ring structure around the central part, wherein the ring structure is configured to be rotatable around the central part, and
a first rotary joint, and
a carrier structure, wherein the carrier structure is attached to the first rotary joint and wherein the carrier structure is adapted to carry the antenna, and wherein the first rotary joint is configured to allow for a manipulation of an elevation of the carrier structure relative to the central part via a rotation of the carrier structure.

7. The measurement arrangement according to claim 5, wherein the opening for the load board frame is formed, such that the measurement arrangement can be attached to and/or removed from the test head, while the load board is attached to the load board frame which is attached to the test head.

8. The measurement arrangement according to claim 7, wherein the measurement arrangement comprises the first rotary joint and a second rotary joint, wherein the rotary joints are attached to opposite sides of the ring structure; and
wherein the first and second rotary joints are arranged, such that they comprise a common rotation axis, wherein the rotation axis and a normal vector of the plane of the central part and/or of the plane of the ring structure are orthogonal, with a tolerance of less than 0.01°, less than 0.1° or less than 1° or less than 5°; and
wherein the carrier structure is attached to the first and the second rotary joint; and
wherein the first and second rotary joints are configured to allow for a manipulation of an elevation of the carrier structure, relative to the central part, via a rotation of the carrier structure around the common rotation axis of the first and second rotary joint.

9. The measurement arrangement according to claim 6, wherein the measurement arrangement is configured to center the antenna, when attached to the carrier structure, over the DUT,
when the DUT is coupled to the load board, and
when the measurement arrangement and the load board are attached to the load board frame, the load board frame being attached to the test head, and when the carrier structure is rotated to a position wherein an elevation between the carrier structure and the load board is 90 degrees.

10. The measurement arrangement according to claim 6, wherein the ring structure comprises a plurality of bearing elements; and wherein the ring structure is supported by the central part via the bearing elements, such that the ring structure can rotate around the central part.

11. The measurement arrangement according to claim 1, wherein the measurement arrangement comprises an absorptive structure and wherein the absorptive structure is configured to absorb electromagnetic waves.

12. The measurement arrangement according to claim 1, wherein the measurement arrangement comprises a calibration reference antenna, wherein the calibration reference antenna is configured to provide a reference signal for a calibration of the measurement antenna.

13. A measurement setup comprising
a measurement arrangement according to claim 1; and
the load board frame, wherein the load board frame is configured to be coupled with the load board; and
wherein the load board frame is configured to be attached to the test head; and
wherein the measurement arrangement is configured to be attached to the load board frame.

14. The measurement setup according to claim 13, wherein the load board frame is configured to provide for a spacing between the test head and the load board; and
wherein the load board frame is configured to allow for a routing of one or more cables for feeding signals from the test head to the load board, and/or to allow for a routing of one or more cables for guiding signals from the load board to the test head and/or to allow for a routing of one or more cables from the test head to the measurement arrangement and/or to allow for a storing of additional components in the spacing.

15. A measurement system comprising:
a test head;
a load board; and
a measurement setup according to claim 13;
wherein the load board frame is attached to the test head; and
wherein the load board is mechanically coupled to the load board frame.

16. The measurement system according to claim 15, wherein the measurement arrangement is configured to be controlled by the test head, and wherein the measurement arrangement is configured to manipulate the position of the antenna and/or to provide a measurement information for determining the beamforming characteristic of the DUT, in response to a control signal provided by the test head.

17. The measurement system according to claim 15, wherein the measurement arrangement comprises one or more control modules; and
wherein the one or more control modules are configured to control the actuator; and/or
wherein the antenna is configured to provide a plurality of measurement signals, and
wherein the one or more control modules are configured to control a selection of a measurement signal of the plurality of measurement signals of the antenna.

18. The measurement system according to claim 15,
wherein the test head is configured to test a plurality of DUTs, when the DUTs are electrically coupled to the load board;
wherein the test head is configured to perform a plurality of tests on the plurality of DUTs; and
wherein the test head is configured to perform one or more tests of the plurality of tests temporally in parallel on a plurality of devices under test.

19. The measurement system according to claim 18, wherein the test head is configured to provide a test signal for determining a beamforming characteristic of a DUT, temporally parallel to a testing of one or more DUTs.

20. A method for determining a beamforming characteristic of a device under test (DUT), using an automated test equipment (ATE) and a measurement arrangement, the method comprising:
manipulating a position of an antenna, carried by the measurement arrangement, relative to the DUT,
while the DUT is coupled to a load board, and while the load board is electrically coupled to a test head of the ATE, and
wherein the measurement arrangement is attached to the test head of the ATE or to a load board frame attached to the test head of the ATE; and
determining the beamforming characteristic of the device under test (DUT).
